(19) United States
(12) Patent Application Publication
(10) Pub. No.: US 2022/0077366 A1
(43) Pub. Date: Mar. 10, 2022

(54) LIGHT SOURCE MODULE AND MANUFACTURING METHOD THEREOF

(71) Applicant: Primax Electronics Ltd., Taipei (TW)

(72) Inventors: Ya-Chin Tu, Taipei (TW); Hung-Wei Kuo, Taipei (TW)

(21) Appl. No.: 17/082,217

(22) Filed: Oct. 28, 2020

(30) Foreign Application Priority Data
Sep. 4, 2020 (TW) 109130454

(51) Int. Cl. H01L 33/62; H01L 33/54; H01L 25/075

(52) U.S. Cl. CPC H01L 33/62; H01L 33/54; H01L 2933/005; H01L 2933/0066; H01L 25/0753

(57) ABSTRACT

A light source module includes a transparent conductive substrate and a light-emitting element. The light-emitting element is installed on the transparent conductive film, and electrically connected with the transparent conductive film. The light-emitting element is flip-chip LED, and/or the light-emitting element is not equipped with a lead frame. Moreover, the present invention further provides a manufacturing method of the light source module.

### FIELD OF THE INVENTION

The present invention relates to an optical device, and more particularly to a light source module and a manufacturing method of the light source module.

### BACKGROUND OF THE INVENTION

With the development of electronic industries and the advance of industrial technologies, various electronic products are designed toward small size, slimness, light weightiness and easy portability. Consequently, these electronic products can be applied to mobile business, entertainment or leisure purposes whenever or wherever the users are. Recently, people pay much attention to the integrations and applications of mechanical, optical and electrical technologies. Consequently, a variety of light source modules are gradually and extensively applied to various electronic products. For example, a light source module is applied to a casing of a computer for electronic sports. Consequently, the casing of the computer can provide an awesome luminous effect.

Please refer to FIGS. 1 and 2. FIG. 1 is a schematic perspective view illustrating the appearance of a conventional light source module in an off state. FIG. 2 is a schematic cross-sectional view illustrating a portion of the light source module as shown in FIG. 1. The light source module 1 comprises a transparent conductive substrate 11, plural light emitting diode units 12, a protective glass plate 13 and an encapsulant structure 14. The encapsulant structure 14 is filled in the space between the transparent conductive substrate 11 and the protective glass plate 13. The light emitting diode units 12 are electrically connected with a conductive layer 111, which is disposed on the transparent conductive substrate 11. Consequently, when the light emitting diode units 12 acquire electric power through the transparent conductive substrate 11, the light emitting diode units 12 are enabled to emit light beams. The light emitting diode units 12 are protected by the protective glass plate 13 and the encapsulant structure 14. Consequently, the problems of dampening and scratching the light emitting diode units 12 will be avoided.

Each light emitting diode unit 12 of the light source module 1 is produced by packaging a light emitting diode die 121. For example, the light emitting diode unit 12 comprises the light emitting diode die 121 and a lead frame 122. The light emitting diode die 121 is installed on the lead frame 122 and electrically coupled to the lead frame 122 through a wire bonding process. The lead frame 122 is installed on the transparent conductive substrate 11. Moreover, the lead frame 122 comprises an electric connection part 124. The lead frame 122 is electrically connected with the conductive layer 111 of the transparent conductive substrate 11 through the electric connection part 124.

However, the conventional light source module 1 still has some drawbacks. Firstly, due to the package structure of the light emitting diode die 121, the volume of the lead frame 122 and the height of the wire 123 are detrimental to the thickness reduction of the light emitting diode unit 12. Generally, the thickness H1 of the portion of the light source module 1 overlying the transparent conductive substrate 11 is larger than 3 mm. Since it is difficult to reduce the thickness of the light source module 1, the electronic device with the light source module 1 cannot meet the requirements of light weightiness, slimness and small size. Secondly, the lead frame 122 is not a light-transmissible structure, the transmittance of the light source module 1 is influenced, and the light source module 1 is unable to provide the double-side luminous effect. Thirdly, when the light source module 1 is disabled, the light emitting diode unit 12 is still clearly visible. Consequently, the clean and simple visual effect cannot be provided. Fourthly, if the light source module 1 is bent, the wire 123 of the light emitting diode unit 12 is possibly broken or detached. For solving this drawback, the transparent conductive substrate 11 is made of a rigid material only. However, the flexible property of the light source module 1 is adversely affected.

In other words, the conventional light source module needs to be further improved.

### SUMMARY OF THE INVENTION

An object of the present invention provides a light source module, and the light source module is a combination of a low-impedance transparent conductive substrate and a flip-chip LED.

Another object of the present invention provides a light source module, and the light source module is a combination of a low-impedance transparent conductive substrate and a light-emitting element without a lead frame.

A further object of the present invention provides a manufacturing method of a light source module.

In accordance with an aspect of the present invention, a light source module is provided. The light source module includes a transparent conductive substrate and at least one flip-chip LED. The transparent conductive substrate includes a transparent substrate base and a transparent conductive film. The transparent conductive film is installed on the transparent substrate base. The at least one flip-chip LED is installed on the transparent conductive film and electrically connected with the transparent conductive film. The flip-chip LED acquires electric power through the transparent conductive film, so that the flip-chip LED is enabled to emit a light beam.

In accordance with an aspect of the present invention, a light source module is provided. The light source module includes a transparent conductive substrate and at least one light-emitting element. The transparent conductive substrate includes a transparent substrate base and a transparent conductive film. The transparent conductive film is installed on the transparent substrate base. Each light-emitting element includes an electric connection part and is not equipped with a lead frame. Each light-emitting element is installed on the transparent conductive film, and electrically connected with the transparent conductive film through the electric connection part. Each light-emitting element acquires electric power through the transparent conductive film, so that the light-emitting element is enabled to emit a light beam.

In an embodiment, the flip-chip LED is a mini LED.

In an embodiment, the transparent substrate base is a glass substrate base, a polyethylene terephthalate (PET) substrate base or a polymethylmethacrylate (PMMA) substrate base.

In an embodiment, the transparent conductive layer is made of indium tin oxide (ITO) or a liquid crystal polymer mixture material (PEDOT), or the transparent conductive layer is a stack structure comprising an indium tin oxide layer, a metal layer and an indium tin oxide layer.

In an embodiment, the transparent conductive substrate is made of a rigid material or a flexible material.

In an embodiment, a thickness of a portion of the light source module overlying the transparent conductive substrate is not larger than 0.25 mm.

In an embodiment, the light source module further includes a first protective layer. The first protective layer is located over the transparent conductive film.

In an embodiment, the light source module further includes a second protective layer. The second protective layer is located over the at least one flip-chip LED.

In accordance with a further aspect of the present invention, a manufacturing method of a light source module is provided. In a step (a), a transparent conductive film is formed on a transparent substrate base. In a step (b), at least one flip-chip LED is installed on the transparent conductive film. The at least one flip-chip LED is electrically connected with the transparent conductive film.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating the appearance of a conventional light source module in an off state;

FIG. 2 is a schematic cross-sectional view illustrating a portion of the light source module as shown in FIG. 1;

FIG. 3 is a schematic perspective view illustrating the appearance of a light source module in an off state according to an embodiment of the present invention;

FIG. 4 is a schematic cross-sectional view illustrating a portion of the light source module as shown in FIG. 3;

FIG. 5 is a flowchart of a method for manufacturing a light source module according to an embodiment of the present invention;

FIG. 6A is a schematic cross-sectional view illustrating the step S1 of the manufacturing method as shown in FIG. 5;

FIG. 6B is a schematic cross-sectional view illustrating the step S2 of the manufacturing method as shown in FIG. 5;

FIG. 6C is a schematic cross-sectional view illustrating the step S3 of the manufacturing method as shown in FIG. 5;

FIG. 6D is a schematic cross-sectional view illustrating the step S4 of the manufacturing method as shown in FIG. 5;

FIG. 6E is a schematic cross-sectional view illustrating the step S5 of the manufacturing method as shown in FIG. 5; and

FIG. 6F is a schematic cross-sectional view illustrating the step S6 of the manufacturing method as shown in FIG. 5.

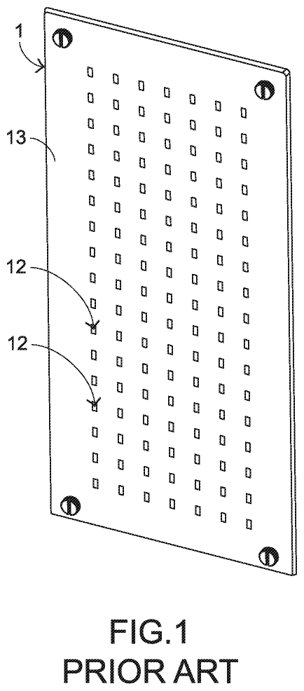

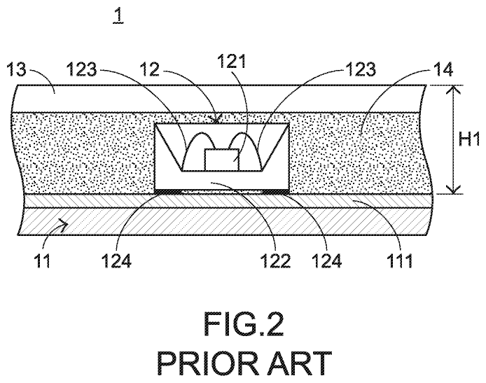

### DETAILED DESCRIPTION OF THE PREFERRED EMBODIMENT

The embodiments of present invention will be described more specifically with reference to the following drawings. Generally, in the drawings and specifications, identical or similar components are designated by identical numeral references. For well understanding the present invention, the elements shown in the drawings are not in scale with the elements of the practical product. In the following embodiments and drawings, the elements irrelevant to the concepts of the present invention or the elements well known to those skilled in the art are omitted. It is noted that numerous modifications and alterations may be made while retaining the teachings of the invention.

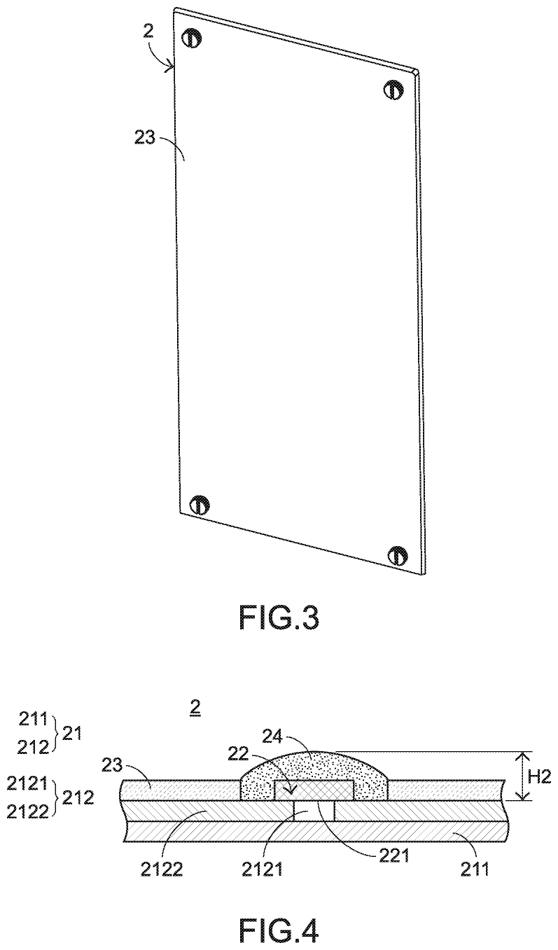

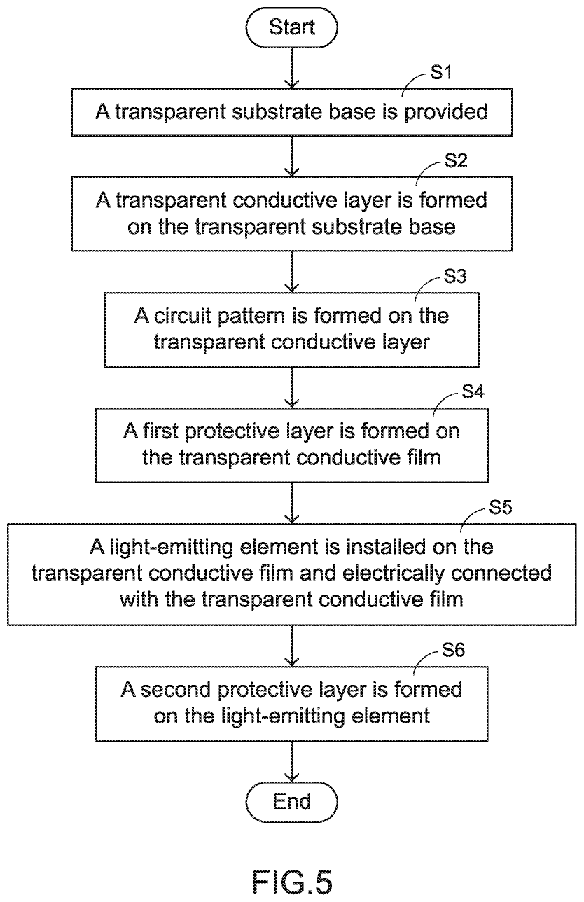

Please refer to FIGS. 3 and 4. FIG. 3 is a schematic perspective view illustrating the appearance of a light source module in an off state according to an embodiment of the present invention. FIG. 4 is a schematic cross-sectional view illustrating a portion of the light source module as shown in FIG. 3. The light source module 2 comprises a transparent conductive substrate 21, plural light-emitting elements 22. The transparent conductive substrate 21 comprises a transparent substrate base 211 and a transparent conductive film 212. The transparent conductive film 212 is installed on the transparent substrate base 211. The transparent conductive film 212 has a circuit pattern 2121. The light-emitting elements 22 are installed on the circuit pattern 2121 and electrically connected with the circuit pattern 2121. For example, the transparent conductive substrate 21 is made of a rigid material or a flexible material.

Each light-emitting element 22 is a light source with an electric connection part 221. Especially, the light-emitting element 22 is not equipped with a lead frame. For example, the light-emitting element 22 is a flip-chip LED. Preferably but not exclusively, the flip-chip LED is a Mini LED. The light-emitting elements 22 are electrically connected with the circuit pattern 2121 on the transparent conductive film 212 through the corresponding electric connection parts 221. Consequently, when the light-emitting elements 22 acquire electric power through the transparent conductive film 212, the light-emitting elements 22 are enabled to emit light beams.

Preferably, the light source module 2 further comprises a first protective layer 23 and a second protective layer 24. The first protective layer 23 is located over the transparent conductive substrate 21. The second protective layer 24 is located over the light-emitting elements 22. Consequently, the light-emitting elements 22 and the circuit pattern 2121 of the transparent conductive film 212 can be protected from scratch or oxidation. The first protective layer 23 and the second protective layer 24 are made of transparent material.

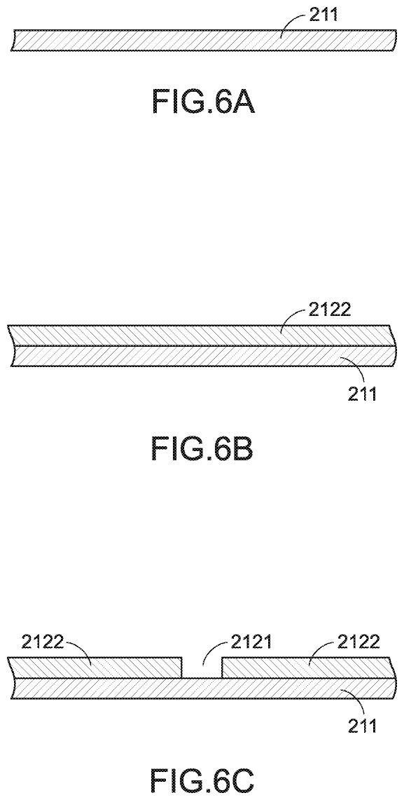

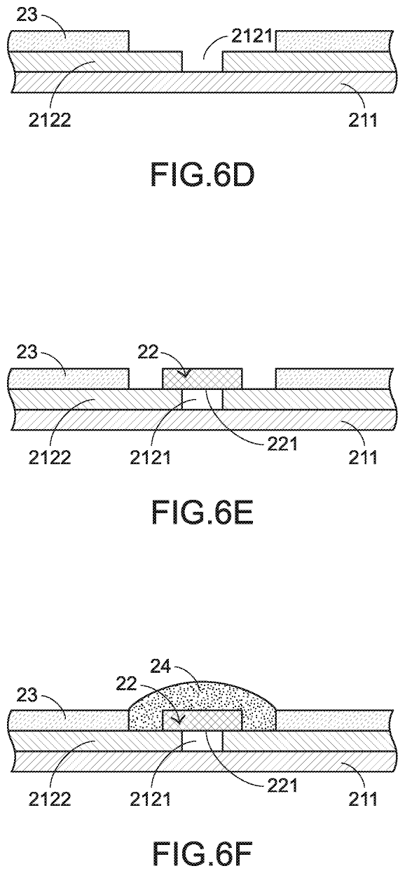

Please refer to FIG. 5 and FIGS. 6A˜6F. FIG. 5 is a flowchart of a method for manufacturing a light source module according to an embodiment of the present invention. FIGS. 6A˜6F are schematic cross-sectional views illustrating the manufacturing method of FIG. 5. The manufacturing method of the light source module comprises the following steps.

Please refer to FIG. 6A. Firstly, in a step S1, a transparent substrate base 211 is provided. Preferably but not exclusively, the transparent substrate base 211 is a glass substrate base, a polyethylene terephthalate (PET) substrate base or a polymethylmethacrylate (PMMA) substrate base.

Please refer to FIG. 6B. In a step S2, a transparent conductive layer 2122 is formed on the transparent substrate base 211. For example, the transparent conductive layer 2122 is made of indium tin oxide (ITO) or a liquid crystal polymer mixture material (e.g., PEDOT). Alternatively, the transparent conductive layer 2122 is a stack structure comprising an indium tin oxide layer, a metal layer and an indium tin oxide layer. In other words, the transparent conductive layer 2122 can be directly grown on the transparent substrate base 211, and the transparent conductive layer 2122 can be a stack structure with different material layers. Consequently, the impedance of the transparent conductive substrate 21 is reduced, and the optical transmittance is enhanced.

Please refer to FIG. 6C. In a step S3, a circuit pattern 2121 is formed on the transparent conductive layer 2122. Consequently, a transparent conductive film 212 is produced. For example, the circuit pattern 2121 is formed through a photomask process, an exposure process, an etching process and/or any other appropriate semiconductor manufacturing process. The processes of forming the circuit pattern 2121 are well known to those skilled in the art, and not redundantly described herein.

Please refer to FIG. 6D. In a step S4, a first protective layer 23 is formed on the transparent conductive film 212. The first protective layer 23 is made of epoxy resin, methyl methacrylate (Arcylic), silicone or hybrid material, which is coated, printed or dispensed on the transparent conductive film 212. The first protective layer 23 can protect the circuit pattern 2121 of the transparent conductive film 212. Moreover, the first protective layer 23 can be adhered on the transparent conductive film 212.

Please refer to FIG. 6E. In a step S5, a light-emitting element 22 is installed on the transparent conductive film 212 and electrically connected with the transparent conductive film 212. For example, the light-emitting element 22 is a flip-chip LED. Preferably but not exclusively, the flip-chip LED is a Mini LED.

Please refer to FIG. 6F. In a step S6, a second protective layer 24 is formed on the light-emitting element 22. The second protective layer 24 is made of epoxy resin, methyl methacrylate (Arcylic), silicone or hybrid material, which is coated, printed or dispensed on the light-emitting element 22.

From the above descriptions, the light source module 2 of the present invention has the following advantages. Firstly, since the light-emitting element 22 is not equipped with the lead frame, the thickness of the light source module is reduced. Consequently, the electronic device with the light source module 2 can meet the requirements of light weightiness, slimness and small size. Preferably but not exclusively, the thickness H2 of the portion of the light source module 2 overlying the transparent conductive substrate 21 is not larger than 0.25 mm. Secondly, the light source module 2 is able to provide the double-side luminous effect. Thirdly, it is not necessary to perform a cutting process and a wire bonding process. Consequently, the manufacturing method of the light source module 2 is simplified. In case that the transparent conductive substrate 21 is made of the flexible material, the flexibility and the variability of the light source module 2 are increased. Fourthly, the light source module 2 is suitably applied to a large-size module, e.g., the mechanism with a size larger than 500 mm×200 mm. Fifthly, the light beams are stable and uniform. Sixthly, when the light source module 2 is disabled, the light emitting diode unit 22 is not easily observed by the naked eyes. Consequently, the light source module 2 can provide the clean and simple visual effect.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A light source module, comprising:
a transparent conductive substrate comprising a transparent substrate base and a transparent conductive film, wherein the transparent conductive film is installed on the transparent substrate base; and
at least one flip-chip LED installed on the transparent conductive film and electrically connected with the transparent conductive film, wherein the flip-chip LED acquires electric power through the transparent conductive film, so that the flip-chip LED is enabled to emit a light beam.

2. The light source module according to claim 1, wherein the flip-chip LED is a mini LED.

3. The light source module according to claim 1, wherein the transparent substrate base is a glass substrate base, a polyethylene terephthalate (PET) substrate base or a polymethylmethacrylate (PMMA) substrate base.

4. The light source module according to claim 1, wherein the transparent conductive layer is made of indium tin oxide (ITO) or a liquid crystal polymer mixture material (PEDOT), or the transparent conductive layer is a stack structure comprising an indium tin oxide layer, a metal layer and an indium tin oxide layer.

5. The light source module according to claim 1, wherein the transparent conductive substrate is made of a rigid material or a flexible material.

6. The light source module according to claim 1, wherein a thickness of a portion of the light source module overlying the transparent conductive substrate is not larger than 0.25 mm.

7. The light source module according to claim 1, wherein the light source module further comprises a first protective layer and/or a second protective layer, wherein the first protective layer is located over the transparent conductive film, and the second protective layer is located over the at least one flip-chip LED.

8. A light source module, comprising:
a transparent conductive substrate comprising a transparent substrate base and a transparent conductive film, wherein the transparent conductive film is installed on the transparent substrate base; and
at least one light-emitting element, wherein each light-emitting element comprises an electric connection part and is not equipped with a lead frame, wherein each light-emitting element is installed on the transparent conductive film, and electrically connected with the transparent conductive film through the electric connection part, wherein each light-emitting element acquires electric power through the transparent conductive film, so that each light-emitting element is enabled to emit a light beam.

9. The light source module according to claim 8, wherein the light-emitting element is flip-chip LED.

10. The light source module according to claim 8, wherein the light-emitting element is a mini LED.

11. The light source module according to claim 8, wherein the transparent substrate base is a glass substrate base, a polyethylene terephthalate (PET) substrate base or a polymethylmethacrylate (PMMA) substrate base.

12. The light source module according to claim 8, wherein the transparent conductive layer is made of indium tin oxide (ITO) or a liquid crystal polymer mixture material (PEDOT), or the transparent conductive layer is a stack structure comprising an indium tin oxide layer, a metal layer and an indium tin oxide layer.

13. The light source module according to claim 8, wherein the transparent conductive substrate is made of a rigid material or a flexible material.

14. The light source module according to claim 8, wherein a thickness of a portion of the light source module overlying the transparent conductive substrate is not larger than 0.25 mm.

15. The light source module according to claim 8, wherein the light source module further comprises a first protective layer and/or a second protective layer, wherein the first protective layer is located over the transparent conductive film, and the second protective layer is located over the at least one light-emitting element.

16. A manufacturing method of a light source module, the manufacturing method comprising steps:
(a) forming a transparent conductive film on a transparent substrate base; and
(b) installing at least one flip-chip LED on the transparent conductive film, wherein the at least one flip-chip LED is electrically connected with the transparent conductive film.

17. The manufacturing method according to claim 16, wherein the step (a) comprises steps of:
(a1) forming a transparent conductive layer on the substrate base; and
(a1) forming a circuit pattern on the transparent conductive layer, and allowing the at least one flip-chip LED to be electrically connected with the circuit pattern.

18. The manufacturing method according to claim 17, wherein the transparent conductive layer is made of indium tin oxide (ITO) or a liquid crystal polymer mixture material (PEDOT), or the transparent conductive layer is a stack structure comprising an indium tin oxide layer, a metal layer and an indium tin oxide layer.

19. The manufacturing method according to claim 16, wherein the flip-chip LED is a mini LED.

20. The manufacturing method according to claim 16, wherein the transparent substrate base is a glass substrate base, a polyethylene terephthalate (PET) substrate base or a polymethylmethacrylate (PMMA) substrate base.
